(19) United States
(12) Patent Application Publication
(10) Pub. No.: US 2026/0346223 A1
(43) Pub. Date: Nov. 5, 2026

(54) PLASMA APPARATUS AND METHODS FOR CRACKING A GAS

(71) Applicant: ACADEMIA SINICA, Taipei (TW)

(72) Inventors: James C. LIAO, Taipei (TW); Yang-Yuan CHEN, Taipei (TW); Min-Nan OU, Taipei (TW); Shan-Luo WU, Taichung (TW)

(21) Appl. No.: 18/997,518

(22) PCT Filed: Jul. 21, 2023
(86) PCT No.: PCT/US2023/070654

§ 371 Date: Jan. 22, 2025

Related U.S. Application Data
(60) Provisional application No. 63/391,421, filed on Jul. 22, 2022.

(51) Int. Cl. B01J 19/08; C01B 3/24; C01B 32/05; H05H 1/48

(52) U.S. Cl. CPC B01J 19/088; C01B 3/24; C01B 32/05; H05H 1/48; B01J 2219/0818; B01J 2219/083; B01J 2219/0875; B01J 2219/0896; B01J 2219/185; H05H 2245/10

(57) ABSTRACT

The present disclosure relates to a plasma apparatus and a method. The plasma apparatus comprises an inner electrode and an outer electrode. The inner electrode comprises a wall defining a first cavity, and an opening of the first cavity is configured to receive a first gas. The outer electrode surrounds the inner electrode. The inner electrode has a through-hole extending through the wall of the inner electrode, such that the first cavity is in fluid communication with a plasma generation region between the inner electrode and the outer electrode via the through-hole. The inner electrode is rotatable about a first axis of rotation, and the first axis of rotation extends through the first cavity. In particular, some embodiments of the present disclosure relate to a plasma apparatus and a method for cracking a gas.

### BACKGROUND OF THE INVENTION

### Related Application

This application claims priority to U.S. Provisional Patent Application Ser. No. 63/391,421, filed on Jul. 22, 2022, entitled “Method for simultaneous production of carbon and hydrogen by plasma cracking of hydrocarbon gas,” which is incorporated herein by reference in its entirety.

### Field of the Invention

The present disclosure relates to a plasma apparatus and a method. In particular, some embodiments of the present disclosure relate to a plasma apparatus and a method for cracking a gas.

### Description of Related Art

Plasma is considered the fourth state of matter beyond solid, liquid, and gas. It is defined as a state of matter in which electrons, ions, and electrically neutral particles coexist in the same space. Plasma technology is commonly used in many industries. Using high-energy particles in the plasma to interact with substances can result in enhanced reactions. Based on the operating environment and the working pressure, plasma can be divided into vacuum plasma, atmospheric plasma, and high-pressure plasma; each has its application fields. For example, vacuum plasma is generally used for coating. The material to be coated is made into a target and placed on the cathode. An additional gas such as argon is used as the working gas (or carrier gas), and a voltage is applied to generate plasma from the working gas. The plasma is used to hit the target so that the material is sputtered on the substrate to be coated, thereby achieving coating on the substrate.

Atmospheric plasma is generally used in applications such as surface modification and cleaning. The working gas used in atmospheric plasma treatment may include nitrogen, oxygen, argon, air, or a combination of the aforesaid gases. It is used under atmospheric pressure to generate plasma. The generated plasma is generally applied to the surface of an object for surface treatment applications.

When utilizing plasma to crack hydrocarbons into hydrogen and carbon, the carbon generated during the cracking process will coat the electrodes, which would stop plasma generation and plasma cracking of hydrocarbons. To avoid this issue, nitrogen, oxygen, argon, air, or a combination of the aforesaid gases are used as main working gas to generate plasma. As such, in some cases, only a small amount (e.g., less than 10%) of hydrocarbon gas is allowed to enter the device, and the dissociation efficiency and the product yield are relatively low.

### SUMMARY

According to the present disclosure, a plasma apparatus is provided. The plasma apparatus comprises an inner electrode and an outer electrode. The inner electrode comprises a wall defining a first cavity, and an opening of the first cavity is configured to receive a first gas. The outer electrode surrounds the inner electrode. The inner electrode has a through-hole extending through the wall of the inner electrode, such that the first cavity is in fluid communication with a plasma generation region between the inner electrode and the outer electrode via the through-hole. The inner electrode is rotatable about a first axis of rotation, and the first axis of rotation extends through the first cavity.

In one embodiment, both the inner electrode and the outer electrode are substantially tubular-shaped.

In one embodiment, the outer electrode is arranged coaxially with the inner electrode.

In one embodiment, the plasma apparatus further comprises a rotating member mechanically coupled to the inner electrode, such that the inner electrode is rotatable about the first axis of rotation.

In one embodiment, the rotating member comprises a bearing or a rotor.

In one embodiment, the plasma apparatus further comprises a motor coupled to the inner electrode and configured to provide a rotational driving force to rotate the inner electrode about the first axis of rotation.

In one embodiment, the through-hole is configured to acquire a rotational driving force from a flow of the first gas from the first cavity to the plasma generation region via the through-hole, and the rotational driving force rotates the inner electrode about the first axis of rotation.

In one embodiment, a first angle between an extension direction of the through-hole and a radial direction of the through-hole on a cross-sectional plane of the inner electrode is between about 5 degrees to about 85 degrees, and the cross-sectional plane is perpendicular to a longitudinal axis of the inner electrode.

In one embodiment, a second angle between an extension direction of the through-hole and an axial direction is between about 5 degrees to about 85 degrees, and the axial direction coincides with a longitudinal axis of the inner electrode and extends from a point in the first cavity toward the opening of the first cavity.

In one embodiment, the plasma apparatus further comprises a gas inlet configured to enable a flow of the first gas into the first cavity.

In one embodiment, the plasma apparatus further comprises a gas container coupled to the gas inlet, and the gas container contains the first gas.

In one embodiment, the plasma apparatus further comprises an insulating layer arranged in an annular shape between the outer electrode and the inner electrode.

In one embodiment, the plasma apparatus further comprises a power supply electrically connected to both the inner electrode and the outer electrode, and the power supply is configured to provide a voltage between the inner electrode and the outer electrode.

In one embodiment, the plasma apparatus further comprises a scraping unit configured to contact and move with respect to an outer surface of the inner electrode.

In one embodiment, the scraping unit surrounds the outer surface of the inner electrode and is configured to move in a first direction along a longitudinal axis of the inner electrode and a second direction opposite the first direction.

In one embodiment, the scraping unit comprises a first blade, a second blade, and a connector connecting the first blade and the second blade. The first blade is configured to contact and move with respect to the outer surface of the inner electrode, and the second blade is configured to contact and move with respect to an inner surface of the outer electrode.

In one embodiment, the plasma apparatus further comprises an outlet configured to output a second gas and a solid product produced from the first gas.

In one embodiment, the plasma apparatus further comprises a separation device connected to the outlet, the separation device configured to separate the solid product from the second gas. In one embodiment, the separation device comprises a dust collector and a filter screen connected to the dust collector.

In one embodiment, the plasma apparatus further comprises a bottom cover connected to the outer electrode at an end of the outer electrode, and the outlet is disposed at the bottom cover. In one embodiment, the outer electrode comprises a gas pipeline embedded in a wall of the outer electrode, and the gas pipeline is configured to introduce the first gas into the plasma generation region.

In one embodiment, the first gas comprises a hydrocarbon gas.

According to the present disclosure, a method is provided. The method comprises introducing a first gas into a first cavity defined by a wall of an inner electrode through an opening of the first cavity. The method comprises flowing the first gas from the first cavity to a plasma generation region between the inner electrode and an outer electrode surrounding the inner electrode via a through-hole extending through the wall of the inner electrode. The method comprises generating a plasma in the plasma generation region by applying a voltage between the inner electrode and the outer electrode. The method comprises cracking the first gas using the plasma. The method comprises rotating the inner electrode about a first axis of rotation, and the first axis of rotation extends through the first cavity.

In one embodiment, generating the plasma comprises generating the plasma from a portion of the first gas.

In one embodiment, the first gas comprises a hydrocarbon gas.

In one embodiment, the method further comprises outputting a product produced from the cracking of the first gas from an outlet.

In one embodiment, the product comprises a second gas and a solid product.

In one embodiment, the method further comprises separating the solid product from the second gas by a separation device.

In one embodiment, the method further comprises inputting the second gas to a power generator.

In one embodiment, rotating the inner electrode comprises acquiring a rotational driving force from a flow of the first gas from the first cavity to the plasma generation region via the through-hole.

In one embodiment, rotating the inner electrode comprises providing a rotational driving force from a motor coupled to the inner electrode.

In one embodiment, the method further comprises comprising removing a solid product attached to the inner electrode by a scraping unit.

In one embodiment, the method further comprises cooling the inner electrode through a flow of the first gas from the first cavity to the plasma generation region via the through-hole.

In one embodiment, introducing the first gas comprises introducing the first gas from a gas container into the first cavity.

In one embodiment, the method further comprises heating the first gas before the first gas is introduced into the first cavity.

In one embodiment, the method further comprises introducing the first gas into the plasma generation region through a gas pipeline embedded in a wall of the outer electrode.

### BRIEF DESCRIPTION OF THE DRAWINGS

FIGS. 1A and 1B are schematic diagrams of a plasma apparatus according to one embodiment of the present disclosure.

FIG. 2 is a schematic diagram of a plasma apparatus according to one embodiment of the present disclosure.

FIGS. 3A and 3B are schematic diagrams of an inner electrode according to one embodiment of the present disclosure.

FIG. 4 is a schematic diagram of an inner electrode according to one embodiment of the present disclosure.

FIGS. 5A and 5B are schematic diagrams of a scraping unit according to one embodiment of the present disclosure.

FIG. 6 is a schematic cross-sectional view of a scraping unit according to one embodiment of the present disclosure.

FIG. 7 is a schematic diagram of a plasma apparatus according to one embodiment of the present disclosure.

FIG. 8 is a schematic diagram of a plasma apparatus according to one embodiment of the present disclosure.

FIG. 9 is a flow chart illustrating a method according to one embodiment of the present disclosure.

### DETAILED DESCRIPTION OF PREFERRED EMBODIMENTS

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section. Components and achievement of a plasma apparatus, according to the present disclosure may be illustrated in the following drawings and embodiments. However, the size and shape shown on drawings for the plasma apparatus do not limit the features of the present disclosure.

The phrase “on” used in this application can mean directly on or indirectly on with intervening elements or layers. The spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the apparatus in use or operation in addition to the orientation depicted in the figures. For example, if the apparatus in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

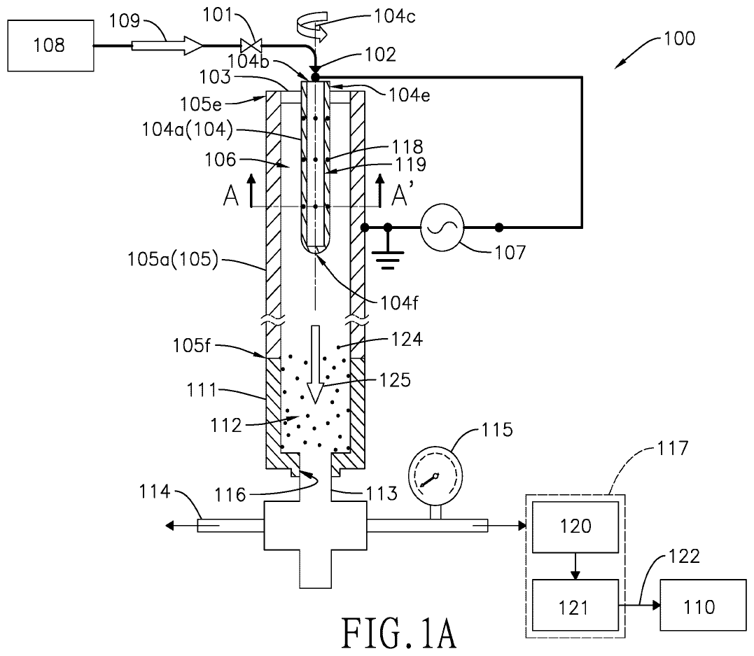

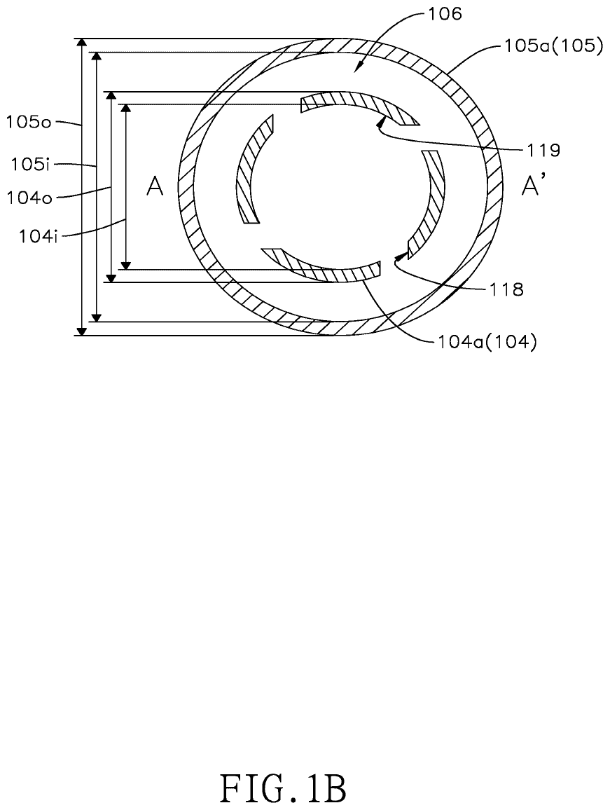

FIGS. 1A and 1B are schematic diagrams of a plasma apparatus according to one embodiment of the present disclosure. FIG. 1B is a schematic cross-sectional view of the plasma apparatus in FIG. 1A along the line A-A′. As shown in FIGS. 1A and 1B, a plasma apparatus 100 comprises an inner electrode 104 and an outer electrode 105. The inner electrode 104 comprises a wall 104a defining a first cavity 119, wherein an opening 104b of the first cavity 119 is configured to receive a first gas 109. The outer electrode 105 surrounds the inner electrode 104 and defines a plasma generation region 106 between the inner electrode 104 and the outer electrode 105. The inner electrode 104 may have a through-hole 118 extending through the wall 104a of the inner electrode 104, such that the first cavity 119 is in fluid communication with the plasma generation region 106 between the inner electrode 104 and the outer electrode 105 via the through-hole 118. As such, a first gas 109 is able to flow into the first cavity 119 through the opening 104b and then to the plasma generation region 106 via the through-hole 118. In some embodiments, the inner electrode 104 may have a plurality of through-holes 118 extending through the wall 104a of the inner electrode 104.

The inner electrode 104 may comprise stainless steel, copper, graphite, molybdenum, aluminum, any suitable conductive materials, or combinations thereof. The outer electrode 105 may comprise stainless steel, aluminum, any suitable conductive materials, or combinations thereof. In the embodiment shown in FIGS. 1A and 1B, the inner electrode 104 is substantially tubular-shaped, and the opening 104b of the first cavity 119 is located at a first end 104e of the inner electrode 104. A second end 104f of the inner electrode 104 opposite to the first end 104e may be closed. However, the disclosure is not limited thereto. The outer electrode 105 may also be substantially tubular-shaped. In some embodiments, the outer electrode 105 is arranged coaxially with the inner electrode 104. In some embodiments, a gap between the inner electrode 104 and the outer electrode 105 is constant. Despite illustrating the inner electrode 104 and the outer electrode 105 having constant radius along the longitudinal axis thereof, in some embodiments, the radius of the inner electrode 104 and the outer electrode 105 may be varied along the longitudinal axis thereof. For example, the inner electrode 104 and/or the outer electrode 105 may be hollow conical shaped.

As shown in FIGS. 1A and 1B, the outer electrode 105 surrounds the second end 104f of the inner electrode 104. In some embodiments, a length of the inner electrode 104 is smaller than a length of the outer electrode 105. In some embodiments, the inner electrode 104 may have a length from about 20 mm to about 300 mm. In some embodiments, the outer electrode 105 may have a length from about 30 mm to about 500 mm. The inner electrode 104 may have an inner diameter 104i from about 5 mm to about 50 mm and an outer diameter 1040 from about 20 mm to about 70 mm. The wall 104a of the inner electrode 104 may have a thickness from about 7.5 mm to about 10 mm. The outer electrode 105 may have an inner diameter 105i from about 25 mm to about 100 mm and an outer diameter 1050 from about 30 mm to about 110 mm. The wall 105a of the outer electrode 105 may have a thickness from about 2.5 mm to about 5 mm. These values are merely examples and are not intended to be limiting.

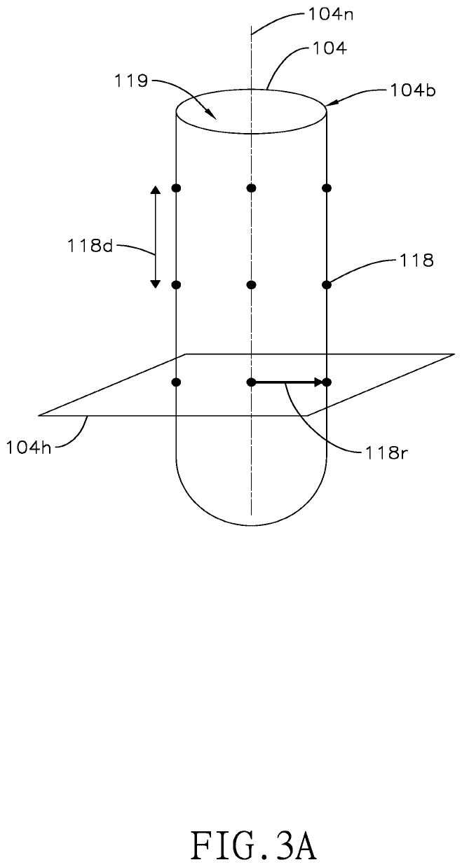

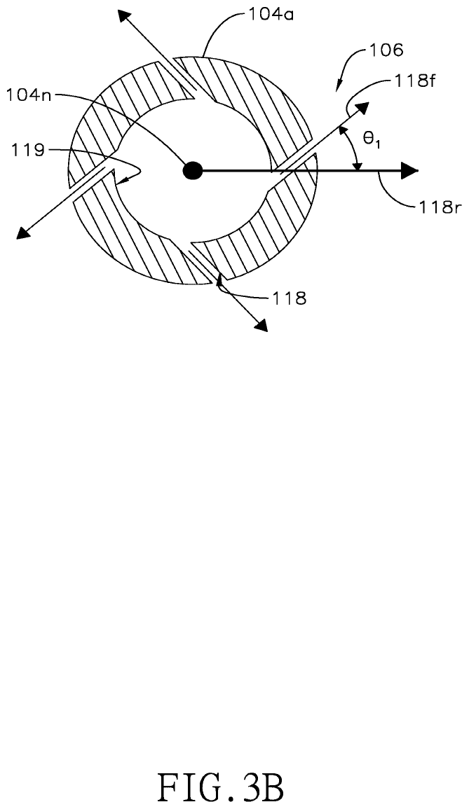

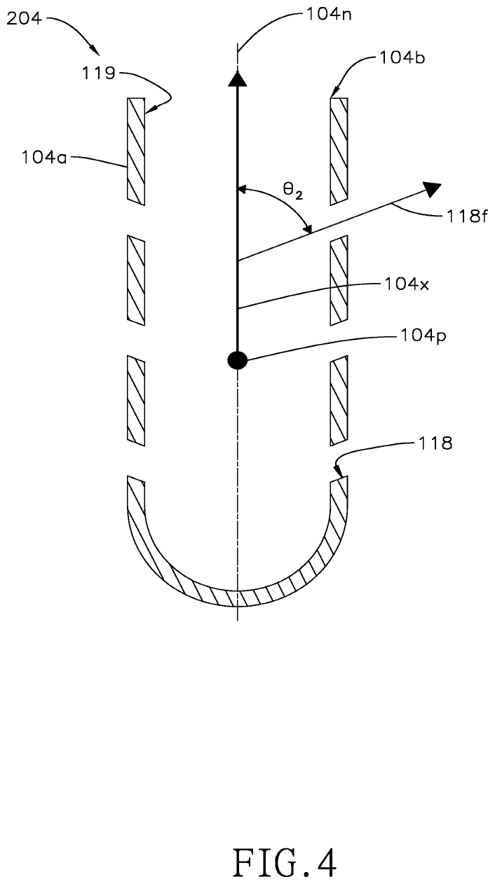

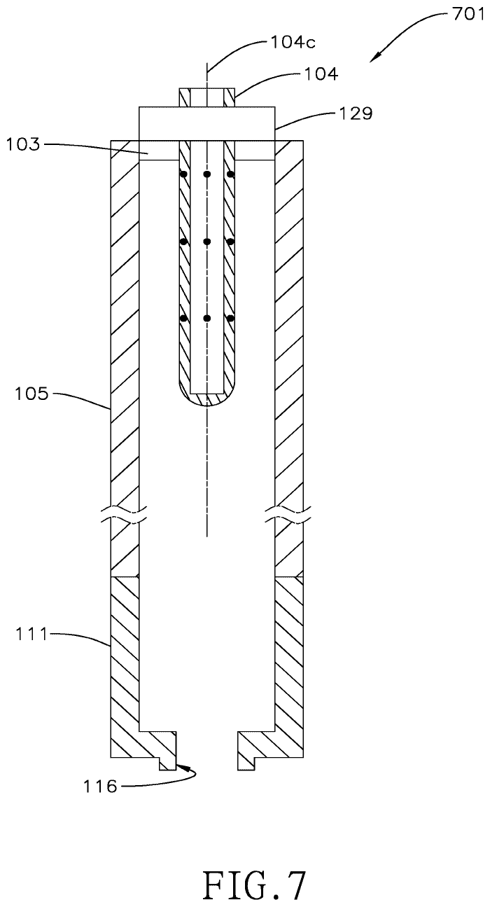

The inner electrode 104 is rotatable about a first axis of rotation 104c, wherein the first axis of rotation 104c extends through the first cavity 119 of the inner electrode 104. In some embodiments, the first axis of rotation 104c may coincide with a longitudinal axis (e.g., the longitudinal axis 104n shown in FIGS. 3A, 3B, and 4) of the inner electrode 104. In other words, the inner electrode 104 may be rotatable about the longitudinal axis thereof. The longitudinal axis herein may refer to an axis along the lengthwise direction, e.g., from the first end 104e to the second end 104f of the inner electrode 104, and passing through a center of gravity thereof. Specifically, the plasma apparatus 100 is configured such that the inner electrode 104 can be driven to rotate, especially when the plasma apparatus 100 is in operation. In some embodiments, the plasma apparatus further comprises a device such as a motor to provide a rotational driving force to rotate the inner electrode (as described below in greater detail with respect to FIG. 7). In some embodiments, the inner electrode may be configured to be driven to rotate by a flow of the first gas passing through the wall of the inner electrode (as described below in greater detail with respect to FIGS. 3A and 3B). As such, the problem of accumulation of solid product on an outer surface of the inner electrode 104 during plasma cracking can be relieved, and the plasma apparatus 100 may be able to continue to operate for a reasonable amount of time without introducing additional working gas. Therefore, dissociation efficiency and the product yield may be increased, and undesired side products formed by reaction with additional working gases can be avoided. Also, the frequency of maintenance and the downtime of the plasma apparatus due to accumulation of solid product may be reduced.

As shown in FIGS. 1A and 1B, the plasma apparatus 100 further comprises a gas inlet 102. The gas inlet 102 may be coupled to the inner electrode 104 at the opening 104b of the first cavity 119 and configured to enable a flow of the first gas 109 into the first cavity 119. In some embodiments, the plasma apparatus 100 further comprises a gas container 108. The gas container 108 may contain the first gas 109 and may be coupled to the gas inlet 102 to provide the first gas 109 into the first cavity 119 for plasma cracking. In some embodiments, the gas container 108 may be a pressurized gas container. In one embodiment, the plasma apparatus 100 may further comprise a gas-intake valve 101 configured to control a flow rate of the first gas 109 into the first cavity 119.

In some embodiments, the first gas 109 comprises a hydrocarbon gas such as alkanes, alkenes, cycloalkanes, and aromatic hydrocarbons including but not limited to methane, ethane, propane, butane, ethylene, natural gas, compressed natural gas (CNG), petroleum gas, and a combination thereof. In some embodiments, the first gas 109 may comprise a gas vaporized from a hydrocarbon liquid such as alkanes, alkenes, cycloalkanes, and aromatic hydrocarbons including but not limited to hexane, diesel, gasoline, kerosene, and a combination thereof. The hydrocarbon liquid may be vaporized into a gaseous state through heating by a vaporizer. In some embodiments, the first gas 109 is pure or substantially pure hydrocarbon; wherein impurities may need to be filtered out to provide substantially pure hydrocarbon. In some embodiments, the first gas 109 may be filtered through a filter before flowing into the first cavity 119. In some embodiments, the first gas 109 may be pre-heated before flowing into the first cavity 119, such that the resulting dissociation efficiency of the first gas 109 may be increased. For example, the first gas 109 may flow through a waste-heat recycling system and be heated by waste-heat recycling from a power plant.

In the embodiment shown in FIG. 1A, the plasma apparatus 100 further comprises a power supply 107. The power supply 107 is electrically connected to both the inner electrode 104 and the outer electrode 105 and configured to provide a voltage between the inner electrode 104 and the outer electrode 105, such that a plasma is generated in the plasma generation region 106. In some embodiments, the plasma is generated from a portion of the first gas 109. The plasma may crack molecules of the first gas 109 and break chemical bonds therein. As a result, the first gas 109 may be dissociated, and product(s) such as a second gas 125 and a solid product 124 may be produced. In the situation where the first gas includes hydrocarbons, the hydrocarbon molecules may be dissociated, and carbon and hydrogen may be generated.

In some embodiments, the power supply 107 comprises a direct current (DC) power supply and/or an alternating current (AC) power supply. In the embodiment shown in FIG. 1A, the outer electrode 105 may be grounded. In some embodiments, magnitudes of voltage and/or frequency of the power supply can be adjusted to achieve a higher conversion rate and/or a greater energy efficiency.

In the embodiment shown in FIG. 1A, the plasma apparatus 100 may further comprise an insulating layer 103 between the outer electrode 105 and the inner electrode 104. The insulating layer 103 may be arranged in an annular shape and may wrap around a portion of the inner electrode 104 so that the inner electrode 104 is electrically isolated from the outer electrode 105. The insulating layer 103 may comprise Teflon, ceramics, any suitable insulation materials, or combinations thereof. In some embodiments, the insulating layer 103 provides a gas-tight seal to prevent leaking of gases (e.g., the first gas 109 and the second gas 125) from the gap between the inner electrode 104 and the outer electrode 105.

In the embodiment shown in FIG. 1A, the plasma apparatus 100 further comprises a bottom cover 111 connected to the outer electrode 105. Specifically, as shown in FIG. 1A, the insulating layer 103 is coupled to the outer electrode 105 at a first end 105e of the outer electrode 105, and the bottom cover 111 is connected to the outer electrode 105 at a second end 105f opposite to the first end 105e of the outer electrode 105. In some embodiments, the bottom cover 111 may comprise non-conductive materials such as quartz, glass, plastic, any suitable insulation materials, and combinations thereof. In some embodiments, the bottom cover 111 may comprise conductive materials such as stainless steel, any suitable conductive materials, and combinations thereof. The bottom cover 111 may be connected to the outer electrode 105 via a gasket, adhesives, welding, and/or other suitable methods. The connection between the bottom cover 111 and the outer electrode 105 may be gas-tight. With the gas-tight configurations, the plasma apparatus may function without additional outer casing, the dissociation efficiency of the first gas may be increased, and the gas pressure within the outer electrode can be set to a higher pressure (e.g., 100 bar, depending on the gas-tight extent of the plasma apparatus) and may be easy to control. By using a gasket or welding, the connection between the bottom cover 111 and the outer electrode 105 may form a stronger gas-tight seal. As shown in FIG. 1A, the plasma apparatus 100 further comprises an outlet 116. The outlet 116 is configured to output the second gas 125 and the solid product 124 produced from the first gas 109. In the embodiment shown in FIG. 1A, the outlet 116 is disposed at the bottom cover 111. However, the disclosure is not limited thereto.

In the embodiment shown in FIG. 1A, the plasma apparatus 100 further comprises a separation device 117 connected to the outlet 116. The separation device 117 is configured to separate the solid product 124 from the second gas 125. As shown in FIG. 1A, the separation device 117 may comprise a dust collector 120 and a filter screen 121 connected to the dust collector 120. In an embodiment where the first gas 109 comprises hydrocarbon gas, the separation device 117 may separate the solid carbon from the hydrogen gas for subsequent applications. For example, the separated solid carbon can be used as an industrial raw material, and the hydrogen gas can be used to generate electricity with low carbon emission. In some embodiments, the dust collector 120 is configured to collect solid carbon with larger size, and the filter screen 121 is configured to block the fine carbon powder that is not collected by the dust collector 120. The second gas 125 (e.g., hydrogen gas) passing through the separation device 117 may be discharged from a gas outlet 122. In some embodiments, dust collector 120 and filter screen 121 may be selected such that solid carbon with desired particle size can be collected for various applications.

In the embodiment shown in FIG. 1A, the separation device 117 may be connected to the outlet 116 through a four-way pipe 113. An outlet pressure gauge 115 may also be connected to the four-way pipe 113 to detect an output pressure of the outlet gas from the outlet 116. In some embodiments, a sampling port 114 may be connected to the outlet 116 through the four-way pipe 113. The sampling port 114 can be used to monitor the composition of the outlet gas, the dissociation efficiency, etc., such that feedback can be provided to the plasma apparatus 100.

As shown in FIG. 1A, the plasma apparatus 100 is orientated vertically. In some embodiments, the positioning of the plasma apparatus 100 in vertical orientation can improve the efficiency of separation of the solid product 124 (e.g., solid carbon) from the second gas 125 (e.g., hydrogen gas), e.g., by allowing gravity to assist in separating the heavier solid product 124 from the lighter second gas 125. For example, as shown in FIG. 1A, the plasma apparatus 100 may further comprise a reactant collection area 112 beneath the plasma generation region 106. The solid product 124 may descend at the reactant collection area 112 due to gravity. Other orientations of plasma apparatus 100 are also possible (e.g., horizontal positions).

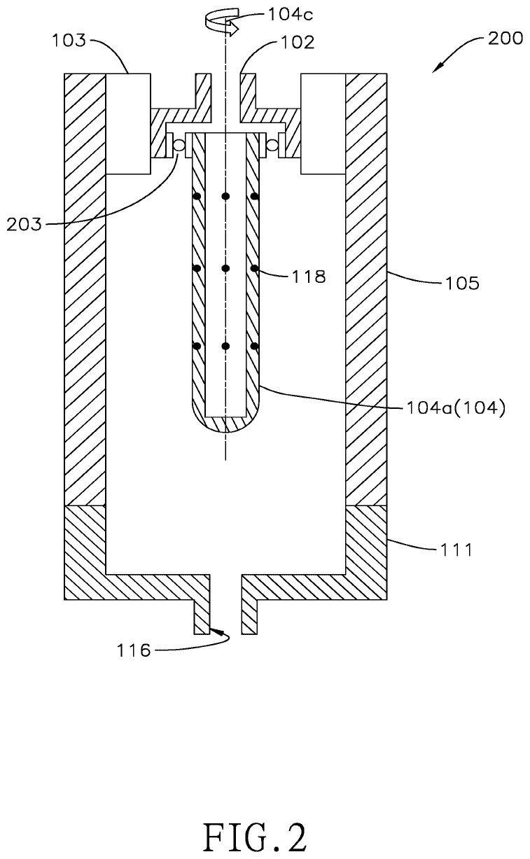

FIG. 2 is a schematic diagram of a plasma apparatus according to one embodiment of the present disclosure. The plasma apparatus 200 in FIG. 2 may be substantially similar to the plasma apparatus 100 in FIGS. 1A and 1B where like reference numerals indicate like elements. As shown in FIG. 2, the plasma apparatus 200 further comprises a rotating member 203. The rotating member 203 is mechanically coupled to the inner electrode 104, such that the inner electrode 104 is rotatable about the first axis of rotation 104c. The rotating member 203 is a mechanical element that constrains the motion of the inner electrode 104 to the desired rotation. The rotating member 203 may also provide mechanical support for the inner electrode 104. In some embodiments, the rotating member 203 comprises a bearing. In some embodiments, the rotating member 203 comprises a rotor. The rotor may be driven to rotate by the interaction between the rotor and a respective stator. However, the disclosure is not limited thereto.

In the embodiment shown in FIG. 2, the rotating member 203 is fixed to the gas inlet 102, and the insulating layer 103 seals the gap between the gas inlet 102 and the outer electrode 105. However, in other embodiments, the rotating member 203 may be fixed to the insulating layer 103, to the outer electrode 105, or to an outer casing when there is any. The disclosure is not limited thereto. As shown in FIG. 2, the rotating member 203 may wrap around the inner electrode 104. The rotating member 203 may be disposed between the inner electrode 104 and the outer electrode 105. In some embodiments, the rotating member 203 is arranged in an annular shape. In some embodiments, the rotating member 203 may be configured to receive a rotational driving force that drives the inner electrode 104 to rotate about the first axis of rotation 104c.

As shown in FIG. 2, the inner electrode 104 has a plurality of through-holes 118 extending through the wall 104a of the inner electrode 104. In some embodiments, the through-hole(s) 118 of the inner electrode 104 is configured to acquire a rotational driving force from a flow of the first gas 109, wherein the rotational driving force rotates the inner electrode 104 about the first axis of rotation 104c. Specifically, the one or more of the through-hole(s) 118 may be configured with an extension direction (as described below in greater detail with respect to FIGS. 3A and 3B) such that when the first gas 109 flows from the first cavity 119 to the plasma generation region 106 via the through-hole 118, the flow may provide a rotational driving force to rotate the inner electrode 104 about the first axis of rotation 104c. As such, the inner electrode 104 can be driven to rotate by the flow of the first gas 109 (e.g., hydrocarbon gas). In this way, the problem of accumulation of solid product (e.g., carbon) on the outer surface of the inner electrode can be relieved due to the rotation of the inner electrode and/or the airflow of the first gas ejected from the through-holes, and the plasma apparatus may be able to continue to operate for a reasonable amount of time without introducing additional working gas; also, the downtime of the plasma apparatus can be reduced. The problem of accumulation of solid product (e.g., carbon) on the inner surface of the outer electrode may also be relieved due to the airflow of the first gas ejected from the through-holes. The airflow of the first gas 109 may also take away heat from the inner electrode 104 to cool the inner electrode 104 and may cool the outer electrode 105 as well. As such, the service life of the inner electrode 104 and/or the outer electrode 105 can be prolonged.

In some embodiments, the rotational speed of the inner electrode 104 may be between about 30 rotations per minute (rpm) to about 180 rpm. However, the disclosure is not limited thereto. In some embodiments, the rotational speed of the inner electrode 104 can be less than 30 rpm or larger than 180 rpm. The rotational speed of the inner electrode 104 may be varied with the size and material thereof, the arrangement and configuration of the through-holes 118, etc. The rotational speed may be controlled by the flow rate of the first gas 109 and may be adjusted to achieve a higher conversion rate and/or a greater energy efficiency. In some cases, such rotation may increase the operable duration of the plasma apparatus from one minute to about 7 days, even to about one month. These values are merely examples and are not intended to be limiting.

FIG. 3A is a schematic diagram of an inner electrode according to one embodiment of the present disclosure. FIG. 3B is a schematic cross-sectional view of the inner electrode in FIG. 3A along a cross-sectional plane 104h, wherein the cross-sectional plane 104h is perpendicular to the longitudinal axis 104n of the inner electrode 104. The inner electrode 104 in FIGS. 3A and 3B may be substantially similar to the inner electrode 104 in FIGS. 1A, 1B, and 2, where like reference numerals indicate like elements. In the embodiment shown in FIG. 3A, the inner electrode 104 has twelve through-holes 118 arranged in three rows each including four through-holes 118 evenly distributed on a circumference (as shown in FIG. 3B, the angle between the adjacent through-holes 118 is substantially 90 degrees). In some embodiments, a row of through-holes 118 may include one to twelve through-holes 118 evenly or unevenly distributed on a circumference. The number and distribution of the through-holes 118 may be varied according to actual needs. In some embodiments, a distance 118d between adjacent rows of through-holes 118 may be from about 5 mm to about 50 mm. In some embodiments, the shape of an opening of a through-hole 118 on the wall 104a may be circular. In some embodiments, the diameter of an opening of a through-hole 118 on the wall 104a may be from about 0.5 mm to about 25 mm. These values are merely examples and are not intended to be limiting.

In some embodiments, the through-holes 118 may be arranged to prolong residence time of the first gas 109 staying in the plasma generation region 106. The prolonged residence time may result in a greater dissociation efficiency of the first gas 109. For example, distribution of the through-holes 118 may be denser (e.g., more through-holes may be included in a row, and/or distance between adjacent rows may be shorter) near the opening 104b, such that the residence time and the resulting dissociation efficiency of the first gas 109 can be increased.

As shown in FIG. 3B, projections of an extension direction 118f and a radial direction 118r of the through-hole 118 on a cross-sectional plane 104h are angled, wherein the radial direction 118r of the through-hole 118 extends from a point at the longitudinal axis 104n of the inner electrode 104 to the through-hole 118, the extension direction 118f of the through-hole 118 extends from the first cavity 119 toward the plasma generation region 106, and the cross-sectional plane 104h refers to a plane perpendicular to the longitudinal axis 104n of the inner electrode 104. As such, when the first gas 109 flows from the first cavity 119 to the plasma generation region 106 via the through-hole 118, the flow may provide a rotational driving force to rotate the inner electrode 104 about the first axis of rotation 104c, and the inner electrode 104 may be able to rotate without additional drive devices.

In some embodiments, a first angle θ₁ between the extension direction 118f of the through-hole 118 and the radial direction 118r of the through-hole 118 on the cross-sectional plane 104h of the inner electrode 104 is between about 5 degrees to about 85 degrees. However, the disclosure is not limited thereto. In some embodiments, the first angle θ₁ can be less than 5 degrees or larger than 85 degrees. The first angle θ₁ may be adjusted to enable a desired rotational speed of the inner electrode 104. In some embodiments, the first angle θ₁ is between about 45 degrees to about 90 degrees. These values are merely examples and are not intended to be limiting.

FIG. 4 is a schematic diagram of an inner electrode according to one embodiment of the present disclosure. The inner electrode 204 in FIG. 4 may be substantially similar to the inner electrode 104 in FIGS. 1A to 3B, where like reference numerals indicate like elements. As shown in FIG. 4, the through-holes 118 may be configured to extend “upward” to prolong the residence time of the first gas 109 staying in the plasma generation region 106. The prolonged residence time may result in a greater dissociation efficiency of the first gas 109. In some embodiments, a second angle θ₂ between the extension direction 118f of the through-hole 118 and the axial direction 104x is between about 5 degrees to about 85 degrees, wherein the axial direction 104x coincides with the longitudinal axis 104n of the inner electrode 104 and extends from a point 104p in the first cavity 119 toward the opening 104b of the first cavity 119. In some embodiments, the second angle θ₂ can be less than 5 degrees or larger than 85 degrees. The second angle θ₂ may be adjusted to achieve a greater dissociation efficiency. In some embodiments, the second angle θ₂ is between about 0 degrees to about 45 degrees. These values are merely examples and are not intended to be limiting.

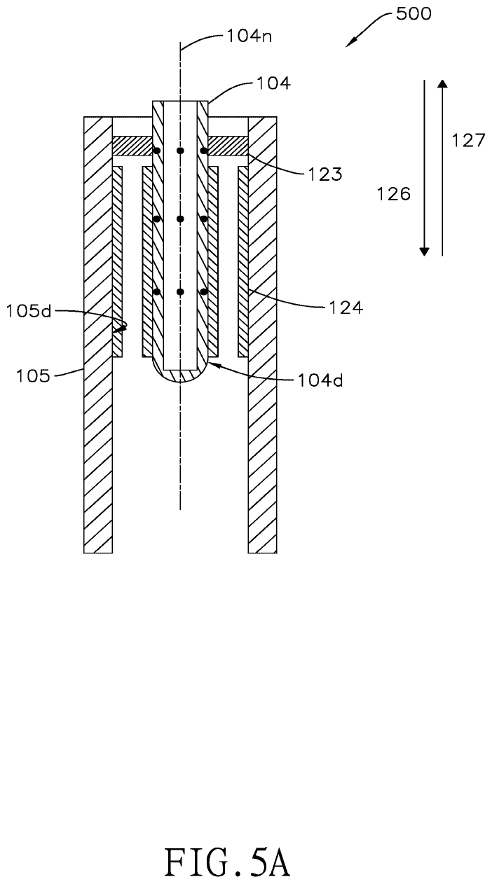

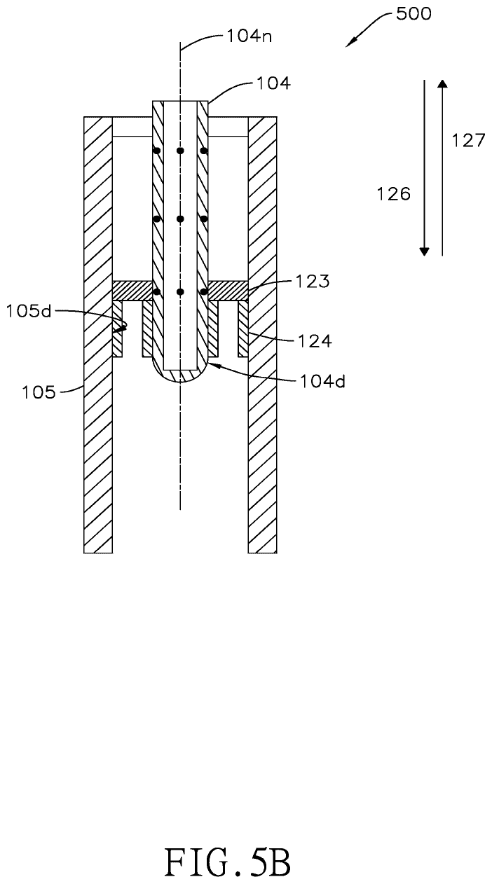

FIGS. 5A and 5B are schematic diagrams of a scraping unit according to one embodiment of the present disclosure. The plasma apparatus 500 in FIGS. 5A and 5B may be substantially similar to the plasma apparatus 100 in FIGS. 1A and 1B where like reference numerals indicate like elements. In the embodiment shown in FIGS. 5A and 5B, the plasma apparatus 500 further comprises a scraping unit 123. The scraping unit 123 is configured to contact and move with respect to an outer surface 104d of the inner electrode 104. The scraping unit 123 may also be configured to contact and move with respect to an inner surface 105d of the outer electrode 105. In some embodiments, the scraping unit 123 surrounds the outer surface 104d of the inner electrode 104 and is configured to move in a first direction 126 along a longitudinal axis 104n of the inner electrode 104 and a second direction 127 opposite the first direction 126. In some embodiments, accumulation of the solid product 124 depositing on the outer surface 104d of the inner electrode 104 and/or the inner surface 105d of the outer electrode 105 may stop the plasma apparatus 500 from generating plasma. The scraping unit 123 can be used to remove solid product 124 attached to the inner electrode 104 and/or the outer electrode 105, so that operation of the plasma apparatus 500 and plasma cracking of the first gas 109 can be maintained.

As shown in FIGS. 5A and 5B, the scraping unit 123 surrounding the outer surface 104d of the inner electrode 104 may move in the first direction 126 to remove a portion of the solid product 124 deposited on the outer surface 104d of the inner electrode 104 and/or the inner surface 105d of the outer electrode 105. The scraping unit 123 can move in the second direction 127 opposite the first direction 126 and back to the initial position. In some embodiments, the scraping unit 123 can be moved by a control rod (not shown) or a magnet assembly (not shown) connected to the scraping unit 123. The scraping unit 123 can be moved by an actuation device or can be moved manually. In some embodiments, the scraping unit 123 can be used during operation period of the plasma apparatus 500. As such, the frequency of maintenance and the downtime of the plasma apparatus may be further reduced.

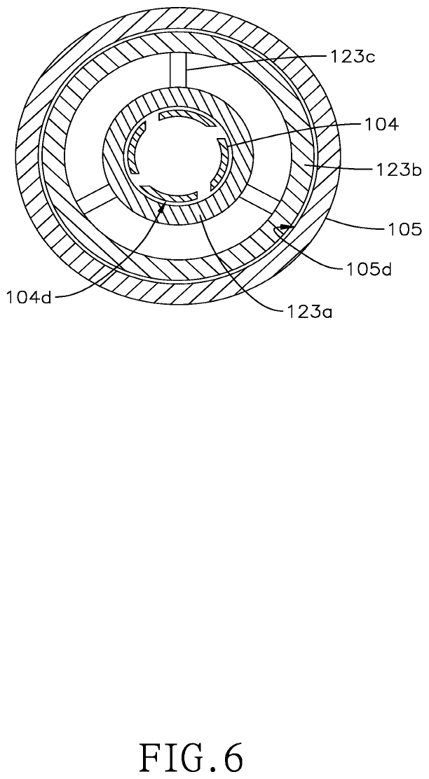

FIG. 6 is a schematic cross-sectional view of a scraping unit according to one embodiment of the present disclosure. In the embodiment shown in FIG. 6, the scraping unit 123 comprises a first blade 123a, a second blade 123b, and a connector 123c connecting the first blade 123a and the second blade 123b. The first blade 123a may be configured to contact and move with respect to the outer surface 104d of the inner electrode 104, and the second blade 123b may be configured to contact and move with respect to an inner surface 105d of the outer electrode 105. The first blade 123a and the second blade 123b may comprise Teflon, metal, ceramics, any suitable insulation materials, or combinations thereof. In some embodiments, the second blade 123b and/or the first blade 123a may comprise iron, any suitable ferromagnetic materials, or combinations thereof, such that the movement of the scraping unit 123 can be controlled by magnetic element(s). In some embodiments, the connector 123c may comprise Teflon, ceramics, any suitable insulation materials, or combinations thereof to avoid short circuit between electrodes.

FIG. 7 is a schematic diagram of a plasma apparatus according to one embodiment of the present disclosure. The plasma apparatus 701 in FIG. 7 may be substantially similar to the plasma apparatus 100 in FIGS. 1A and 1B where like reference numerals indicate like elements. As shown in FIG. 7, the plasma apparatus 701 further comprises a motor 129. The motor 129 may be coupled to the inner electrode 104 and configured to provide a rotational driving force to rotate the inner electrode 104 about the first axis of rotation 104c. The motor 129 may be directly or indirectly coupled to the inner electrode 104. As such, the inner electrode 104 can be driven to rotate by the motor 129. In this way, the problem of accumulation of solid product (e.g., carbon) on the outer surface of the inner electrode can be relieved due to the rotation of the inner electrode, and the downtime of the plasma apparatus can be reduced as described above. The rotational speed of the inner electrode 104 may be controlled by the rotational speed of the motor 129 and may be adjusted to achieve a higher conversion rate and/or a greater energy efficiency. All other descriptions about plasma apparatus and inner electrode described above with respect to FIGS. 1A to 6 may apply here if applicable.

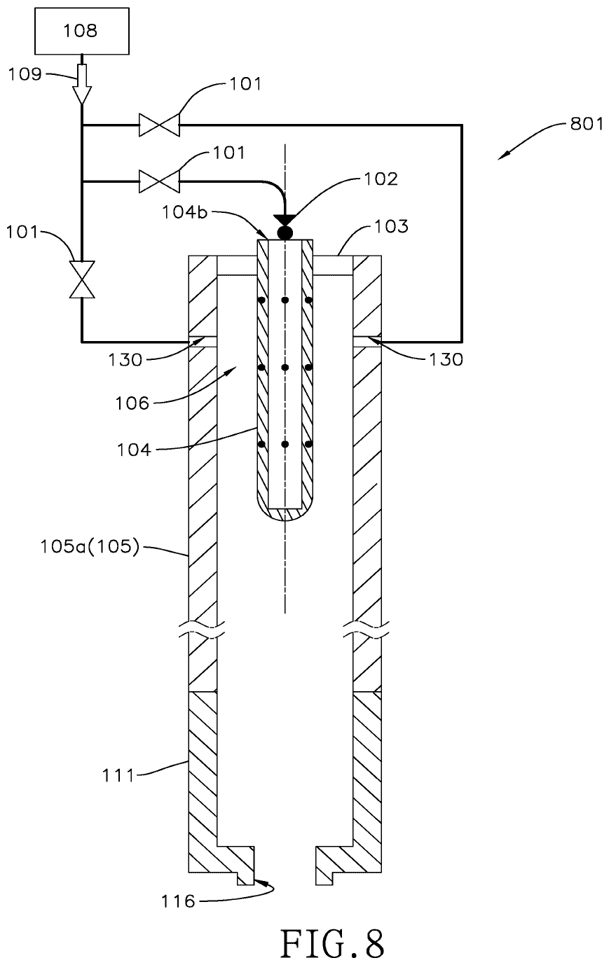

FIG. 8 is a schematic diagram of a plasma apparatus according to one embodiment of the present disclosure. The plasma apparatus 801 in FIG. 8 may be substantially similar to the plasma apparatus 100 in FIGS. 1A and 1B where like reference numerals indicate like elements. As shown in FIG. 8, the outer electrode 105 of the plasma apparatus 801 further comprises a gas pipeline 130. The gas pipeline 130 may be embedded in the wall 105a of the outer electrode 105. In some embodiments, the outer electrode 105 may have a plurality of gas pipelines 130. In one embodiment, the plasma apparatus 801 may further comprise a gas-intake valve 101 configured to control a flow rate of the first gas 109 into the plasma generation region 106. In some embodiments, the gas pipeline 130 is configured to introduce the first gas 109 into the plasma generation region 106. In other words, a first gas 109 is able to flow into the plasma generation region 106 via the gas pipeline 130. In this way, the problem of accumulation of solid product (e.g., carbon) on the outer surface of the inner electrode and/or the inner surface of the outer electrode can be relieved due to the airflow of the first gas ejected from the gas pipeline, and the downtime of the plasma apparatus 801 can be further reduced. The airflow of the first gas 109 may also take away heat from the outer electrode 105 to cool the outer electrode 105 and may cool the inner electrode 104 as well. As such, the service life of the outer electrode 105 and/or the inner electrode 104 can be prolonged.

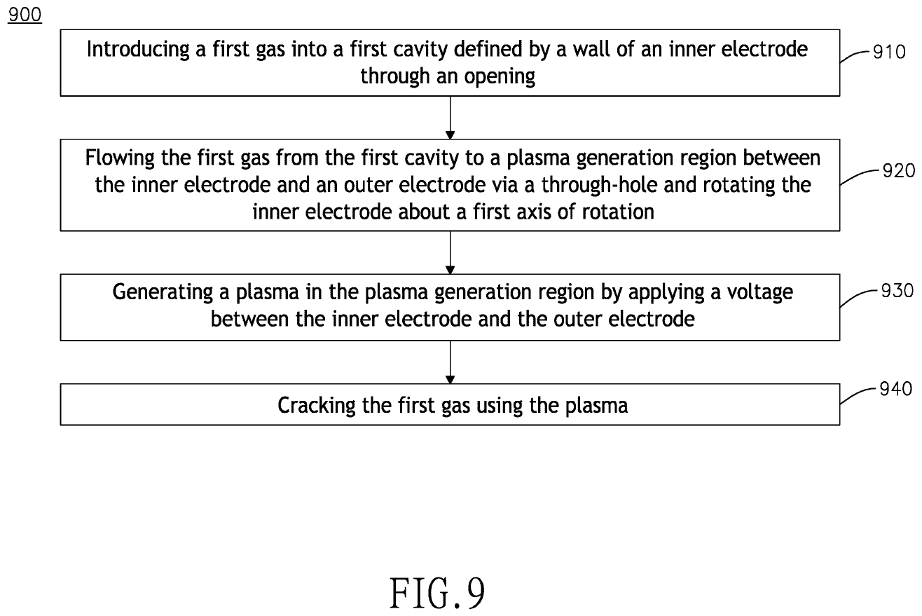

FIG. 9 is a flow chart illustrating a method according to one embodiment of the present disclosure. The method 900 may be operable on a plasma apparatus, e.g., the plasma apparatus 100, the plasma apparatus 200, the plasma apparatus 500, the plasma apparatus 701, and the plasma apparatus 801 as discussed above. In some embodiments, an inner electrode of the plasma apparatus may include any or all of the features, properties, and parameters discussed above with respect to FIGS. 2 to 4.

Referring to FIG. 9 and FIGS. 1A to 1B, the method 900 comprises introducing a first gas 109 into a first cavity 119 through an opening 104b of the first cavity 119 (step 910). The first cavity 119 may be defined by a wall 104a of an inner electrode 104. In some embodiments, the first gas 109 comprises a hydrocarbon gas. In some embodiments, the step 910 may include introducing the first gas 109 from a gas container 108 into the first cavity 119. In some embodiments, the method 900 may include heating the first gas 109 before the first gas 109 is introduced into the first cavity 119. All other descriptions about plasma apparatus described above with respect to FIGS. 1A to 8 may apply here if applicable.

Referring to FIG. 9 and FIGS. 1A to 1B, the method 900 comprises flowing the first gas 109 from the first cavity 119 to a plasma generation region 106 via a through-hole 118 and rotating the inner electrode 104 about a first axis of rotation 104c (step 920). As described above, the plasma generation region 106 is a region between the inner electrode 104 and the outer electrode 105 surrounding the inner electrode 104. The through-hole 118 extends through the wall 104a of the inner electrode 104. The first axis of rotation 104c extends through the first cavity 119 of the inner electrode 104. Further referring to FIGS. 2, 3A, and 3B, in some embodiments, rotating the inner electrode 104 comprises acquiring a rotational driving force from a flow of the first gas 109 from the first cavity 119 to the plasma generation region 106 via the through-hole 118 as described above. Further referring to FIG. 7, in some embodiments, rotating the inner electrode 104 comprises providing a rotational driving force from a motor 129 coupled to the inner electrode 104 as described above. All other descriptions about plasma apparatus and inner electrode described above with respect to FIGS. 1A to 8 may apply here if applicable.

Referring to FIG. 9 and FIGS. 1A to 1B, the method 900 comprises generating a plasma in the plasma generation region 106 by applying a voltage between the inner electrode 104 and the outer electrode 105 (step 930). In some embodiments, generating the plasma comprises generating the plasma from a portion of the first gas 109. In other words, the method can be performed without introducing additional working gas (e.g., nitrogen, oxygen, argon, and air). As such, dissociation efficiency and the product yield of the method may be increased, and undesired side products formed by reaction with additional working gases can be avoided. The plasma may be a cold or non-thermal plasma, and the plasma apparatus may remain at a relatively lower temperature. For example, the plasma may be generated under non-thermodynamic conditions such that effective electron temperatures of about 1000 °C to about 2000 °C or higher are achieved while the bulk gas temperature remains at about less than 500 °C. This may avoid the problem of undesired side products with high molecular weight (e.g., higher hydrocarbons, polycyclic compounds) formed when hot or thermal plasma (e.g., plasma with a bulk gas temperature at about 2000 °C) is used to crack hydrocarbons, which reduces the purity of the produced product.

Referring to FIG. 9 and FIGS. 1A to 1B, the method 900 comprises cracking the first gas 109 using the plasma (step 940). The plasma may crack molecules of the first gas 109 and break chemical bonds therein as described above. In some embodiments, the cracking process occurs in the plasma generation region 106. In some embodiments, the method 900 may include outputting a product produced from the cracking of the first gas 109 from an outlet 116. In some embodiments, the product may comprise a second gas 125 and a solid product 124. In the situation where the first gas 109 includes hydrocarbons, the second gas 125 may comprise hydrogen gas, and the solid product 124 may comprise solid carbon. In some embodiments, a portion of uncracked first gas 109 and/or other impurities may be outputted from an outlet 116. In some embodiments, the second gas 125 may comprise decarbonized hydrocarbon gas (e.g., a mixture of hydrogen gas and hydrocarbon gas).

Referring to FIG. 9 and FIGS. 1A to 1B, in some embodiments, the method 900 may further include separating the solid product 124 from the second gas 125 by a separation device 117 as described above. In the situation where the first gas 109 includes hydrocarbons, the separation device 117 may separate the solid carbon from the hydrogen gas (or decarbonized hydrocarbon gas). The solid carbon can be used as an industrial raw material such as carbon black. Moreover, the production and the separation of the carbon black may be performed without additional energy. The hydrogen gas or decarbonized hydrocarbon gas may be used for generating electricity with low carbon emission. In some embodiments, the hydrogen gas can be stored in the form of liquid hydrogen, compressed hydrogen, or metal hydride.

Referring to FIG. 9 and FIGS. 1A to 1B, in some embodiments, the method 900 may further include inputting the second gas 125 to a power generator 110. As shown in FIG. 1A, the power generator 110 may be coupled to a gas outlet 122 of the separation device 117. As such, the second gas 125 (e.g., hydrogen gas or decarbonized hydrocarbon gas) passing through the separation device 117 may be discharged from the gas outlet 122 and inputted to the power generator 110. In one embodiment, the power generator 110 may comprise a fuel cell. In one embodiment, the power generator 110 may comprise a turbine or an engine. In some embodiments, due to the gas-tight design of the insulating layer 103 and/or the bottom cover 111 as described above, the second gas 125 may be inputted to the power generator 110 at a required gas pressure (e.g., atmospheric pressure or a higher pressure such as 100 bar) without passing through a pump or compressor. The inputting pressure of the second gas 125 may be controlled e.g., by the gas-intake valve 101.

Referring to FIG. 9 and FIGS. 1A to 1B and further referring to FIG. 2, in some embodiments, the method 900 may further include cooling the inner electrode 104 through a flow of the first gas 109 from the first cavity 119 to the plasma generation region 106 via the through-hole 118 as described above, and the related description is omitted for brevity. In some embodiments, the plasma apparatus may function without an additional cooling system. All other descriptions about plasma apparatus described above with respect to FIGS. 1A to 8 may apply here if applicable.

Referring to FIG. 9 and FIGS. 1A to 1B and further referring to FIGS. 5A to 6, in some embodiments, the method 900 may further include removing a solid product 124 attached to the inner electrode 104 by a scraping unit 123 as described above, and the related description is omitted for brevity. All other descriptions about plasma apparatus described above with respect to FIGS. 1A to 8 may apply here if applicable.

Referring to FIG. 9 and FIGS. 1A to 1B and further referring to FIG. 8, in some embodiments, the method 900 may further include introducing the first gas 109 into the plasma generation region 106 through a gas pipeline 130 embedded in a wall 105a of the outer electrode 105 as described above, and the related description is omitted for brevity. All other descriptions about plasma apparatus described above with respect to FIGS. 1A to 8 may apply here if applicable. The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter. Thus, it is intended that the present invention covers modifications and variations that come within the scope of the appended claims and their equivalents.

What is claimed is:

1. A plasma apparatus, comprising:
an inner electrode comprising a wall defining a first cavity, an opening of the first cavity configured to receive a first gas, the inner electrode being rotatable about a first axis of rotation, wherein the first axis of rotation extends through the first cavity; and
an outer electrode surrounding the inner electrode;
wherein the inner electrode has a through-hole extending through the wall of the inner electrode, such that the first cavity is in fluid communication with a plasma generation region between the inner electrode and the outer electrode via the through-hole.

2. The plasma apparatus of claim 1, wherein both the inner electrode and the outer electrode are substantially tubular-shaped.

3. The plasma apparatus of claim 1, wherein the outer electrode is arranged coaxially with the inner electrode.

4. The plasma apparatus of claim 1 further comprising a rotating member mechanically coupled to the inner electrode, such that the inner electrode is rotatable about the first axis of rotation.

5. The plasma apparatus of claim 4, wherein the rotating member comprises a bearing or a rotor.

6. The plasma apparatus of claim 1 further comprising a motor coupled to the inner electrode and configured to provide a rotational driving force to rotate the inner electrode about the first axis of rotation.

7. The plasma apparatus of claim 1, wherein the through-hole is configured to acquire a rotational driving force from a flow of the first gas from the first cavity to the plasma generation region via the through-hole, and the rotational driving force rotates the inner electrode about the first axis of rotation.

8. The plasma apparatus of claim 1, wherein a first angle between an extension direction of the through-hole and a radial direction of the through-hole on a cross-sectional plane of the inner electrode is between about 5 degrees to about 85 degrees, wherein the cross-sectional plane is perpendicular to a longitudinal axis of the inner electrode.

9. The plasma apparatus of claim 1, wherein a second angle between an extension direction of the through-hole and an axial direction is between about 5 degrees to about 85 degrees, wherein the axial direction coincides with a longitudinal axis of the inner electrode and extends from a point in the first cavity toward the opening of the first cavity.

10. The plasma apparatus of claim 1 further comprising a gas inlet configured to enable a flow of the first gas into the first cavity.

11. The plasma apparatus of claim 10 further comprising a gas container coupled to the gas inlet, wherein the gas container contains the first gas.

12. The plasma apparatus of claim 1 further comprising an insulating layer arranged in an annular shape between the outer electrode and the inner electrode.

13. The plasma apparatus of claim 1 further comprising a power supply electrically connected to both the inner electrode and the outer electrode, wherein the power supply is configured to provide a voltage between the inner electrode and the outer electrode.

14. The plasma apparatus of claim 1 further comprising a scraping unit configured to contact and move with respect to an outer surface of the inner electrode.

15. The plasma apparatus of claim 14, wherein the scraping unit surrounds the outer surface of the inner electrode and is configured to move in a first direction along a longitudinal axis of the inner electrode and a second direction opposite the first direction.

16. The plasma apparatus of claim 15, wherein the scraping unit comprises a first blade, a second blade, and a connector connecting the first blade and the second blade; wherein the first blade is configured to contact and move with respect to the outer surface of the inner electrode, and the second blade is configured to contact and move with respect to an inner surface of the outer electrode.

17. The plasma apparatus of claim 1 further comprising an outlet configured to output a second gas and a solid product produced from the first gas.

18. The plasma apparatus of claim 17 further comprising a separation device connected to the outlet, the separation device configured to separate the solid product from the second gas.

19. The plasma apparatus of claim 18, wherein the separation device comprises a dust collector and a filter screen connected to the dust collector.

20. The plasma apparatus of claim 17 further comprising a bottom cover connected to the outer electrode at an end of the outer electrode, wherein the outlet is disposed at the bottom cover.

21. The plasma apparatus of claim 1, wherein the outer electrode comprises a gas pipeline embedded in a wall of the outer electrode, and the gas pipeline is configured to introduce the first gas into the plasma generation region.

22. The plasma apparatus of claim 1, wherein the first gas comprises a hydrocarbon gas.

23. A method, comprising:
introducing a first gas into a first cavity defined by a wall of an inner electrode through an opening of the first cavity;
flowing the first gas from the first cavity to a plasma generation region between the inner electrode and an outer electrode surrounding the inner electrode via a through-hole extending through the wall of the inner electrode;
generating a plasma in the plasma generation region by applying a voltage between the inner electrode and the outer electrode;
cracking the first gas using the plasma; and
rotating the inner electrode about a first axis of rotation, wherein the first axis of rotation extends through the first cavity.

24. The method of claim 23, wherein generating the plasma comprises generating the plasma from a portion of the first gas.

25. The method of claim 23, wherein the first gas comprises a hydrocarbon gas.

26. The method of claim 23 further comprising outputting a product produced from the cracking of the first gas from an outlet.

27. The method of claim 26, wherein the product comprises a second gas and a solid product.

28. The method of claim 27 further comprising separating the solid product from the second gas by a separation device.

29. The method of claim 27 further comprising inputting the second gas to a power generator.

30. The method of claim 23, wherein rotating the inner electrode comprising acquiring a rotational driving force from a flow of the first gas from the first cavity to the plasma generation region via the through-hole.

31. The method of claim 23, wherein rotating the inner electrode comprising providing a rotational driving force from a motor coupled to the inner electrode.

32. The method of claim 23 further comprising removing a solid product attached to the inner electrode by a scraping unit.

33. The method of claim 23 further comprising cooling the inner electrode through a flow of the first gas from the first cavity to the plasma generation region via the through-hole.

34. The method of claim 23, wherein introducing the first gas comprises introducing the first gas from a gas container into the first cavity.

35. The method of claim 23 further comprising heating the first gas before the first gas is introduced into the first cavity.

36. The method of claim 23 further comprising introducing the first gas into the plasma generation region through a gas pipeline embedded in a wall of the outer electrode.
